(19) United States
(12) Patent Application Publication
(10) Pub. No.: US 2006/0132200 A1
(43) Pub. Date: Jun. 22, 2006

(54) Fractional-N divider, fractional-N phase locked loop and method of dividing a frequency f of an output signal by N, wherein N is a non-integer

(76) Inventor: Markus Dietl, Muenchen (DE)

Correspondence Address: TEXAS INSTRUMENTS INCORPORATED, P O BOX 655474, M/S 3999, DALLAS, TX, 75265, US

(21) Appl. No.: 11/314,991

(22) Filed: Dec. 21, 2005

(30) Foreign Application Priority Data
Dec. 22, 2004 (DE) 10 2004 061920.4

(51) Int. Cl. H03B 19/00

(52) U.S. Cl. 327/117

(57) ABSTRACT

A fractional-N divider for dividing a frequency f of an output signal by N, where N is a non-integer. The fractional-N divider includes an oscillator 209 adapted to provide K output signals I,I=I₁, . . . , I_{K}. Each output signal I has the same frequency f and period T. The output signals I are mutually phase shifted by T/K or a multiple of T/K. The fractional-N divider further comprises a multiplexer 211 adapted to select one signal from the K output signals I. The selected signal is phase shifted by M*T/K in relation to a previously selected signal, where M is an integer. Additionally, the fractional-N divider comprises a counter 206 adapted to receive said selected signal. The counter 206 is adapted to count a predetermined number X of periods of the selected signal, whereupon the counter 206 outputs a counter signal 230. The counter 206 is connected to a control input of the multiplexer 211. The multiplexer 211 is adapted to switch from a currently selected output signal to another selected output signal in response to said counter signal 230.

### CROSS REFERENCE TO RELATED APPLICATIONS

This application claims priority under 35 USC § 119 of German Application Serial No. 10 2004 061920.4, filed Dec. 22, 2004.

### FIELD OF THE INVENTION

The present invention relates to a fractional-N divider, a fractional-N phase locked loop and a method of dividing a frequency f of an output signal by N, wherein N is a non-integer.

### BACKGROUND OF THE INVENTION

Fractional-N dividers are customarily used in fractional-N phase locked loops. With reference to the appended FIG. 1, a fractional-N phase locked loop according to the prior art is described hereinafter. A reference signal 101 and a signal output from a frequency divider 106 are fed to a phase detector 102. The reference signal 101 has a frequency denoted by f_{ref}. The output of the phase detector 102 is a pulse that is related to the phase difference between the reference signal 101 and the output signal of the frequency divider 106. The output of the phase detector 102 is fed to a charge pump 107 and then filtered by a loop filter 108. The output of the loop filter 108 is then applied as a control voltage to a voltage controlled oscillator 109. The output of the voltage controlled oscillator (VCO) 109 is supplied to the input of the frequency divider 106. As a result of this feedback arrangement, the output frequency f of the VCO 109 is driven to be equal the frequency f_{ref} of the reference signal 101 times the division factor N of the frequency divider 106; f=f_{ref}*N. Hence, the output frequency f of the VCO 109 can be controlled by controlling the division factor N of the frequency divider 106.

The frequency divider 106 is typically a counter, which counts to a value X received from a modulator 110. The modulator 110 generates an output signal comprising a succession of values X such that the long-term average of the values X results in a desired frequency in the output 115 of the VCO 109. When wanting to divide by X+M/N, then the Modulator 110 provides (N−M)-times a division factor X to the frequency divider 106. Furthermore, the modulator 110 provides M-times the division factor (X+1) to the frequency divider 106. The frequency divider 106 divides on average by the fractional denominator N equal to [(L−M)*X+(X+1)*L]/Z=X+M/L. The fractional denominator N differs from the actual denominators X and X+1. Consequently, the above fractional divider according to the state of the art generates a lot of jitter at the input of the phase detector 102.

### SUMMARY OF THE INVENTION

The fractional N-divider according to the invention generates less jitter than the conventional fractional N-divider presented above.

The subject matter of the appended claim 1 defines the fractional N-divider according to the present invention. The fractional-N divider comprises an oscillator adapted to provide K output signals I, I=I₁, . . . , I_{K}. Each output signal I has the same frequency f and period T. The output signals I are mutually phase shifted by T/K or a multiple of T/K.

The fractional-N divider according to the present invention further comprises a multiplexer adapted to select one predetermined signal from the K output signals I. The selected signal is phase shifted by M*T/K in relation to a previously selected signal, where M is an integer. A counter is adapted to receive said selected signal and count a predetermined number X of periods of the selected signal, whereupon the counter outputs a counter signal. The counter is connected to a control input of the multiplexer. The multiplexer is adapted to switch from a currently selected output signal to another selected output signal in response to said counter signal.

The output counter signal is a periodic signal having a period T_{count} equal to the predetermined number X of counted periods plus the phase shift ±M*T/K provided by the multiplexer; T_{count}=X*T±M*T/K. The fractional denominator N is given by N=f/f_{count}=T_{count}/T=X±M/K. The desired fractional denominator N is not provided by averaging the counter signals. Therefore, no jitter occurs due to deviations from an average counter signal.

Preferably, the fractional-N divider according to the invention is implemented in a fractional-N phase locked loop. The oscillator of the fractional-N divider represents a voltage controlled oscillator of the fractional-N phase locked loop. Any output of the oscillator may be used as fractional-N phase locked loop output, since each of the signals has the same frequency f and period T. The fractional-N phase locked loop further comprises a phase detector having an input connected to the counter for receiving the counter signal and an output connected to an input of the voltage controlled oscillator. The phase detector further receives a reference signal for detecting the phase difference between the counter signal and the reference signal. The output of the phase detector may be connected to the input of the voltage controlled oscillator via a charge pump and a loop filter.

### BRIEF DESCRIPTION OF THE DRAWINGS

A preferred embodiment of the present invention is described hereinafter with reference to the accompanied drawings.

FIG. 1 shows a block diagram of a fractional-N phase locked loop according to the state of the art.

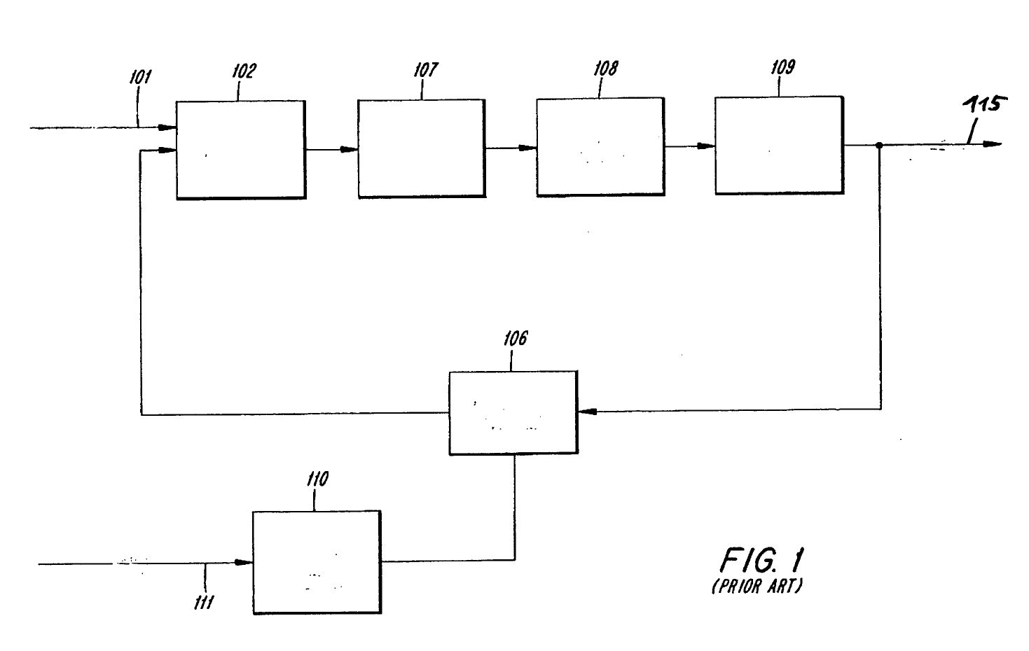

FIG. 2 shows a block diagram of a fractional-N phase locked loop according to the preferred embodiment of the present invention.

FIG. 3 illustrates the phases of the signals output by the oscillator 209 of the preferred embodiment of FIG. 2.

FIG. 4 illustrates schematically signals 215, 220 and 203 output by a voltage controlled oscillator 209, a multiplexer 211, and a counter 206 of the preferred embodiment.

### DETAILED DESCRIPTION OF THE DRAWINGS

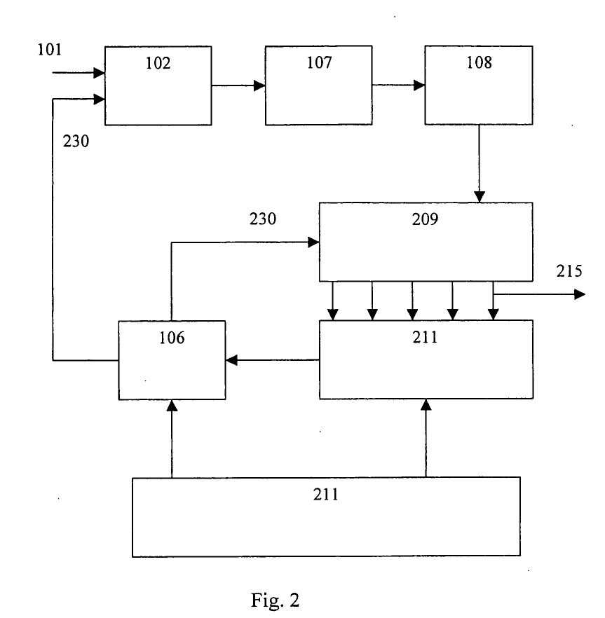

FIG. 2 illustrates the fractional-N phase locked loop according to the preferred embodiment of the present invention. The fractional-N phase locked loop comprises a phase detector 102, which receives a reference signal 101 and a counter signal 230. A signal output by the phase detector 102 is transferred to a voltage controlled oscillator 209 via a charge pump 107 and a loop filter 108. The input to the voltage controlled oscillator 209 is a voltage representative of the phase difference detected at the input of the phase detector 102. The voltage controlled oscillator 209 generates a predetermined number K of output signals I, I=I₁, . . . , I_{K}. Each of the output signals I is a periodic signal having the same period T and frequency f; f=1/T. The frequency f is determined by the voltage input to the voltage controlled oscillator 209. One of the K output signals I represents the output signal 215 of the fractional-N phase locked loop according to the embodiment. All of the output signals I are input to a multiplexer 211, which selects one of the output signals I and provides a select signal 220 to a counter 206. The counter 206 outputs a counter signal 230, which represents a feedback signal input to the phase detector 102. The counter signal 230 is also input to the multiplexer 211 in order to trigger the multiplexer 211. Furthermore, a modulator 210 is provided in the embodiment. Both the counter 206 and the multiplexer 211 are controlled by outputs from the modulator 210. The number of counts X performed by the counter 206 is input to the counter 206 via the modulator 210. Furthermore, the modulator 210 determines which output signal I from the voltage controlled oscillator 209 is to be selected by the multiplexer 211.

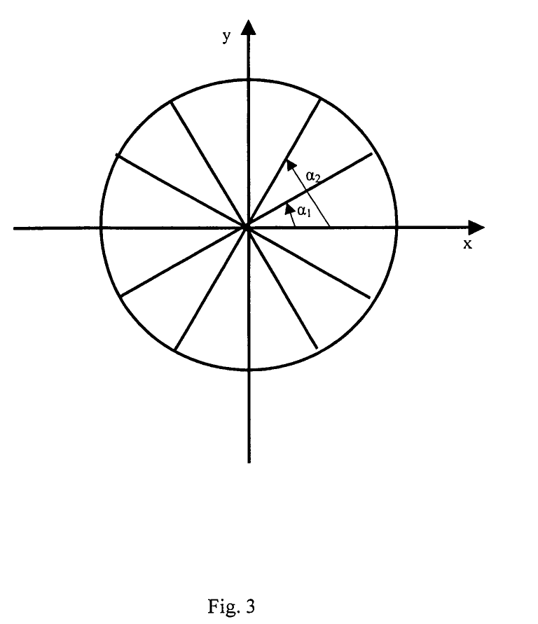

FIG. 3 shows a representation of the angular phase a of the output signals I from the voltage controlled oscillator 209 in FIG. 2. An XY-coordinate system in FIG. 3 comprises a circle having a radius of the length 1. The angle between the X-axis and plural radiuses 1 to K depicted in the circle of FIG. 3 represents the angular phase aI of the signal I output by the voltage controlled oscillator 209. The angular phase is equal to α_{I}=Φ_{I}*2π/T, wherein T represents the period of the output signals I and Φ_{I} is the phase of the output signal I. FIG. 3 illustrates that the phase difference between two adjacent output signals I is equal to ΔΦ_{I,I+1}=T/K, where K represents the number of output signals generated by the voltage controlled oscillator 209. A positive phase shift is achieved by moving along the circle in FIG. 3 in a counter clockwise direction. Conversely, a negative phase shift is achieved by moving along the circle in clockwise orientation.

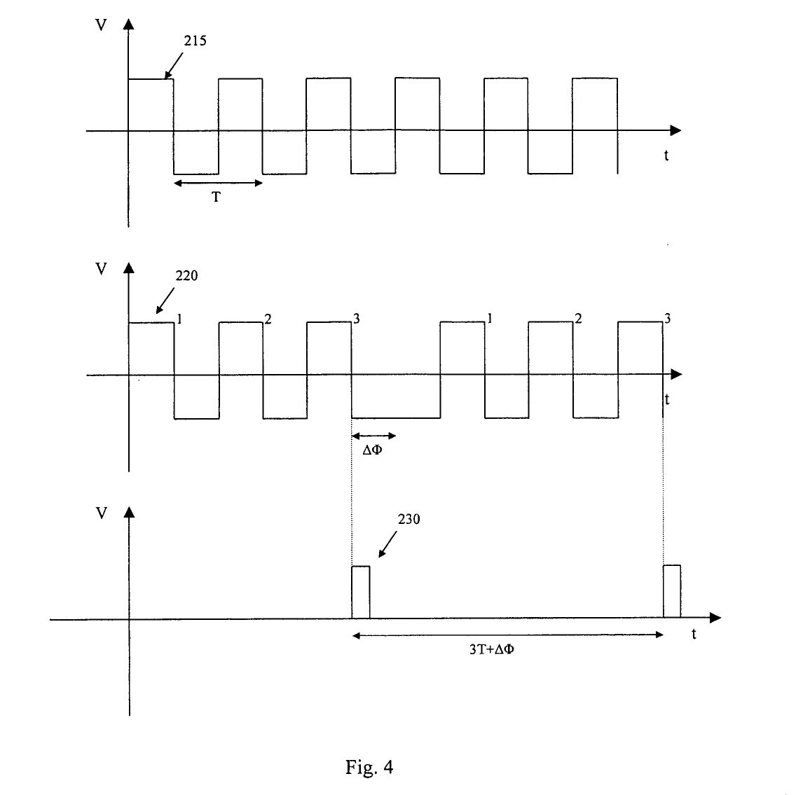

FIG. 4 shows three curves representing the output signal 215 of the phase locked loop of FIG. 2, the select signal 220 from the multiplexer 211 and the counter signal 230 from the counter 206. For each curve, the amplitude V is taken against time t. The depicted signals 215, 220 and 230 may occur, if the phase locked loop of FIG. 2 is in lock, i.e. the output frequency f of the phase locked loop is equal to N times the reference frequency f_{ref} of the reference signal 101. The frequency f_{count} of the counter signal 230 is equal to the frequency f_{ref} of the reference signal 101 at the phase detector 102. The phase detector 102 detects a constant phase shift over time between the reference signal 101 and the counter signal 230. The voltage input to the voltage controlled oscillator 209 is essentially constant over time, so that the output frequency f is constant. T represents the period of the output signal 215 depicted in FIG. 4.

The select signal 220 from the multiplexer 211 is created by periodically shifting between the output signal I from the voltage controlled oscillator 209. Thereby, a phase shift ΔΦ(t,t+1) is provided each time a new signal I is multiplexed. The negative slopes of the select signal 220 from the multiplexer 211 are counted. In the example represented in FIG. 4, the counter 206 counts to 3; X=3. After three negative slopes have entered to the counter 206, the counter 206 returns a counter signal 230 to the multiplexer 211 as well as to the phase detector 102. The counter signal 230 triggers the selection of a new input signal by the multiplexer 211. Thereby, a phase shift ΔΦ(t,t+1) is provided. In the case of FIG. 4, the phase shift ΔΦ(t,t+1) is equal to T/2. Consequently, the next three negative slopes output by the multiplexer 211 are additionally phase shifted by T/2 in relation to the previous three slopes. The next signal output by the counter 206 is delayed by 3*T+T/2. The period T_{count} of the counter signal 230 is equal to T_{count}=3T+T/2 in the case of FIG. 4. The output frequency f divided by f_{count} represents the fractional denominator N=f/f_{count}=T_{count}/T=(3*T+T/2)/T=3+1/2.

In general, the ratio f/f_{count} is equal to [X*T+ΔΦ(t,t+1)]/T. As can be seen in FIG. 3, the phase shift ΔΦ(t,t+1) is equal to ±M*T/K, wherein M is an integer. Consequently, N=f/f_{count}=(X*T±M*T/K)/T=X±M/K. The phase locked loop of FIG. 2 represents a fractional-N phase locked loop, wherein the denominator N is equal to X±M/K.X, M and K each represents whole numbers. X denotes the number of counts performed by the counter 206. K represents the number of signals output from the voltage controlled oscillator 209.

1. A fractional-N divider for dividing a frequency f of an output signal by N, wherein N is a non-integer, comprising:
an oscillator (209) adapted to provide K output signals I,I=I₁, . . . , I_{K}, wherein each output signal I has the same frequency f and period T and the output signals I are mutually phase shifted by T/K or a multiple of T/K;
a multiplexer (211) adapted to select one signal from the K output signals I, the selected signal being phase shifted by M*T/K in relation to a previously selected signal, where M is an integer;
a counter (206) adapted to receive said selected signal and count a predetermined number X of periods of the selected signal, whereupon the counter (206) outputs a counter signal (230); and
wherein the counter (206) is connected to a control input of the multiplexer (211) and the multiplexer (211) is adapted to switch from a currently selected output signal to another selected output signal in response to said counter signal (230).

2. A Fractional-N phase locked loop comprising the fractional-N divider according to claim 1, wherein said oscillator is a voltage controlled oscillator (209), further comprising a phase detector (102) having an input connected to the counter (206) for receiving the counter signal (230) and an output connected to an input of the voltage controlled oscillator (209).

3. A Method of dividing a frequency f of an output signal by N, wherein N is a non-integer, comprising the steps:
generating K output signals I, I=I₁, . . . , I_{K}, wherein each output signal I has the same frequency f and period T and the output signals I are mutually phase shifted by T/K or a multiple of T/K;
selecting one signal from the K output signals I, the selected signal being phase shifted by M*T/K in relation to a previously selected signal, where M is an integer;
counting a predetermined number X of periods of the selected signal, whereupon a counter signal (230) is output; and
switching from a currently selected output signal I to an output signal I phase shifted by M*T/K in response to said counter signal (230).
